(19) United States
(12) Patent Application Publication
(10) Pub. No.: US 2023/0249605 A1
(43) Pub. Date: Aug. 10, 2023

(54) VEHICLE HEADLIGHT DEVICE

(71) Applicant: HONDA MOTOR CO., LTD., Tokyo (JP)

(72) Inventors: Masayoshi TAKORI, Saitama (JP); Yuji TSUCHIYA, Saitama (JP)

(21) Appl. No.: 18/164,632

(22) Filed: Feb. 6, 2023

(30) Foreign Application Priority Data
Feb. 8, 2022 (JP) 2022-018311

(51) Int. Cl. B60Q 1/04

(52) U.S. Cl. CPC B60Q 1/04; B60Q 2300/05

(57) ABSTRACT

Provided is a vehicle headlight device which can improve overlooking of pedestrians by a driver even under adverse conditions such as nighttime or rain at night. A vehicle headlight device 1 includes: a left-side light irradiator provided on a left side of a vehicle so as to irradiate light on a predetermined light distribution region of the vehicle in a first irradiation pattern in which a bright region and dark region are alternately repeated; and a right-side light irradiator provided at a right side of the vehicle so as to irradiate light on the light distribution region in a second irradiation pattern in which a bright region and dark region are alternately repeated. In one embodiment, the first irradiation pattern and second irradiation pattern are identical irradiation patterns.

This application is based on and claims the benefit of priority from Japanese Patent Application No. 2022-018311, filed on 8 February, 2022, the content of which is incorporated herein by reference.

### BACKGROUND OF THE INVENTION

### Field of the Invention

The present invention relates to a vehicle headlight device.

### Related Art

As a vehicle headlight device, a device has been proposed whereby a driver can visually check for pedestrians well, while suppressing dazing of pedestrians (for example, refer to Patent Document 1). The vehicle headlight device of Patent Document 1 configures so as to reduce the illumination amount on the upper body of pedestrians according to the distance to the pedestrian acquired from a pedestrian detection sensor.

Patent Document 1: Japanese Unexamined Patent Application, Publication No.2013-184614

### SUMMARY OF THE INVENTION

However, there is a tendency for accidents increasing due to overlooking a pedestrian in front of a vehicle in a straight road. Although it should be made such overlooking of pedestrians does not occur, the existing vehicle headlight devices are not sufficient means under adverse conditions such as nighttime or rain at night in particular.

The present invention has been made taking account of the above such situation, and has an object of providing a vehicle headlight device which can improve overlooking of pedestrians by a driver even under adverse conditions such as nighttime or rain at night.

According to a first aspect of the present invention, a vehicle headlight device (for example, the vehicle headlight device 1 described later) includes: a left-side photoirradiator (for example, the left-side pattern irradiation lamp 4L as the left-side photoirradiator described later) provided at a left side of a vehicle so as to irradiate light onto a predetermined light distribution region (for example, the light distribution region 16 described later) of the vehicle (for example, the vehicle 2 described later) in a first irradiation pattern in which a bright region (for example, the bright region a1 described later) and a dark region (for example, the dark region a2 described later) are alternately repeated; and a right-side photoirradiator (for example, the right-side pattern irradiation lamp 4R as the right-side photoirradiator described later) provided at a right side of the vehicle so as to irradiate light onto the light distribution region in a second irradiation pattern in which a bright region and a dark region are alternately repeated.

According to a second aspect of the present invention, in the vehicle headlight device as described in the first aspect, the first irradiation pattern and the second irradiation pattern are identical irradiation patterns (for example, the irradiation pattern Pf described later).

According to a third aspect of the present invention, in the vehicle headlight device as described in the first aspect, the first irradiation pattern (for example, the first irradiation pattern Pf1 described later) is an irradiation pattern such that first bright regions (for example, the first bright regions all described later) are arranged in parallel, and the second irradiation pattern (for example, the second irradiation pattern Pf2 described later) is an irradiation pattern such that second bright regions (for example, the second bright regions a12 described later) which intersect the first bright region are arranged in parallel.

With the vehicle headlight device according to the first aspect, by at least any of the irradiation light of the first irradiation pattern from the left-side photoirradiator or the irradiation light of the second irradiation pattern from the right-side photoirradiator, the light/dark pattern in which the bright part and dark part are alternately repeated moves within the silhouette of the moving pedestrian. The presence of the pedestrian during movement is thereby easily recognized from the driver. Overlooking of pedestrians by the driver can be improved even under adverse conditions such as nighttime or rain at night.

With the vehicle headlight device according to the second aspect, the first irradiation pattern and second irradiation pattern are the same irradiation pattern. For this reason, the phase difference at the position of the pedestrian depending on the interval of projection positions between the irradiation light from the left-side photoirradiator and the irradiation light from the right-side photoirradiator is clearly recognizable without causing a mistake due to different irradiation patterns. Therefore, an aspect of the light/dark pattern in which the bright part and dark part are alternately repeated is clearly seen within the silhouette of the moving pedestrian. The presence of the pedestrian during movement is thereby much more reliably recognized from the driver.

With the vehicle headlight device according to the third aspect, the first irradiation pattern is an irradiation pattern such that the first bright regions are arranged in parallel, and the second irradiation pattern is an irradiation pattern such that the second bright regions intersecting the first bright regions are arranged in parallel. For this reason, the phase difference at the position of the pedestrian according to the interval of projection positions between the irradiation light of the first irradiation pattern from the left-side photoirradiator and the irradiation light of the second irradiation pattern from the right-side photoirradiator is clearly recognized without one irradiation pattern causing a mistake due to the other irradiation pattern. Therefore, an aspect of the light/dark pattern in which the bright part and dark part are alternately repeated is clearly seen within the silhouette of the moving pedestrian. The presence of the pedestrian during movement is thereby much more reliably recognized from the driver.

### BRIEF DESCRIPTION OF THE DRAWINGS

FIG. 1 is a schematic diagram shows a vehicle headlight device as an embodiment of the present invention;

FIG. 2 is a conceptual block diagram of a pattern irradiation lamp of the vehicle headlight device in FIG. 1;

FIG. 3 is a view schematically showing a visual property of a person related to a technical concept of the present invention;

FIG. 4 is a schematic diagram in a plan view showing a light distribution area of the vehicle headlight device of an embodiment of the present invention;

FIG. 5 is a schematic diagram showing an aspect of a driving field of vision at night in the vehicle equipped with the vehicle headlight device as an embodiment of the present invention;

FIG. 6 is a schematic diagram showing an aspect of a driving field of view at night in the vehicle equipped with the vehicle headlight device as another embodiment of the present invention;

FIG. 7 is a view showing an aspect of a moving pedestrian being illuminated by the illumination pattern light of the vehicle headlight device as an embodiment of the present invention;

FIG. 8 is a view showing an aspect of a pedestrian moving toward a roadway being illuminated by the illumination pattern light of a vehicle headlight device unrelated to the present invention from the viewpoint of a driver; and

FIG. 9 is a view for explaining the reason for the phenomenon of FIG. 8 occurring.

### DETAILED DESCRIPTION OF THE INVENTION

Hereinafter, an embodiment of the present invention will be explained while referencing the drawings. It should be noted that light distribution area in the following explanation is the irradiation area of light, and irradiation pattern is an irradiation shape of light in the light distribution area.

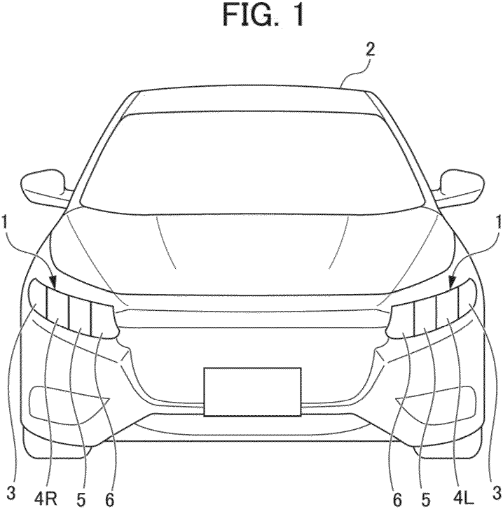

FIG. 1 is a schematic diagram showing a vehicle headlight device 1 of an embodiment of the present invention. The vehicle headlight device 1 is respectively equipped at the left side and right side in a form left/right symmetrical viewing from a central position in the vehicle width direction of a vehicle 2. In order from an outer side in the vehicle-width direction towards the inner side, a turn signal lamp 3, pattern irradiation lamp 4, low beam lamp 5 and high beam lamp 6 are arranged in the vehicle headlight device 1. It should be noted that the pattern irradiation lamp 4 is a general term for the left-side pattern irradiation lamp 4L, which is a left-side photoirradiation part, and right-side pattern irradiation lamp 4R, which is a right-side photoirradiation part.

The turn signal lamp 3 is a normal lamp of this type. In an irradiation pattern in which a bright area and dark area are alternately repeated, the pattern irradiation lamp 4 irradiates this irradiation pattern in the light distribution region of the vehicle. The low beam lamp 5 irradiates light in a predetermined light distribution area of a low beam. The high beam lamp 6 irradiates light in a predetermined light distribution area of a high beam. It should be noted that the vehicle 2 equipped with the vehicle headlight device 1 is abbreviated as one’s own vehicle 2 as appropriate hereinafter.

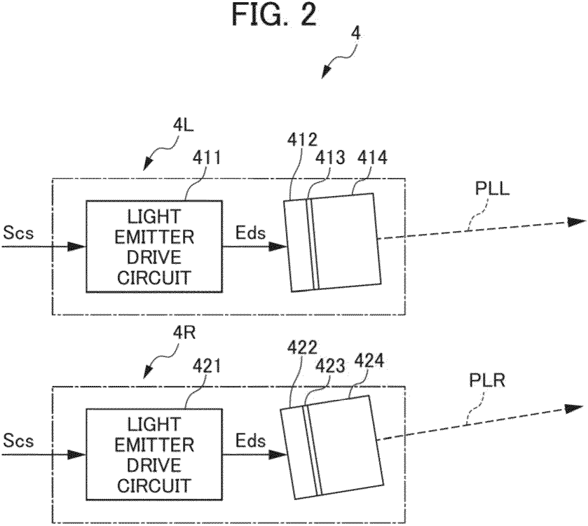

FIG. 2 is a conceptual block diagram of the pattern irradiation lamp 4 in the vehicle headlight device of FIG. 1. The pattern irradiation lamp 4 has the left-side pattern irradiation lamp 4L, which is the left-side photoirradiation part, and the right-side pattern irradiation lamp 4R, which is the right-side photoirradiation part. The left-side pattern irradiation lamp 4L is configured to include a light emitter drive circuit 411, surface emitting element 412, shading mask 413 and projection optical system 414. The right-side pattern irradiation lamp 4R is configured to include a light emitter drive circuit 421, surface emitting element 422, shading mask 423 and projection optical system 424. The shading mask 413 has a light transmission slit corresponding to the first irradiation pattern in which a bright region and dark region are alternately repeated. The shading mask 423 has a light transmission slit corresponding to the second irradiation pattern in which a light region and dark region are alternately repeated. In one embodiment of the present invention, the first irradiation pattern and second irradiation pattern are the same irradiation pattern.

It should be noted that, in practice, between the light emitter drive circuit 411 and surface emitting element 412 of the left-side pattern irradiation lamp 4L, and between the light emitter drive circuit 421 and surface emitting element 422 of the right-side pattern irradiation lamp 4R are arranged to be separated, and are linked by a harness. By configuring in this way, between the light emitter drive circuit and surface emitting element are thermally isolated.

The light emitter drive circuit 411 of the left-side pattern irradiation lamp 4L supplies the element drive signal Eds to the surface emitting element 412 in response to the startup command signal Scs supplied from the lamp control ECU which is not illustrated. The surface emitting element 412 emits light in response to the element drive signal Eds. By the emission of the surface emitting element 412, the left-side irradiation light PLL of the first irradiation pattern is irradiated towards the light distribution region 16 described later, through the shading mask 413 and projection optical system 414.

The light emitter drive circuit 421 of the right-side pattern irradiation lamp 4R supplies the element drive signal Eds to the surface emitting element 422 in response to the startup command signal Scs supplied from the lamp control ECU which is not illustrated. The surface emitting element 422 emits light in response to the element drive signal Eds. By the emission of the surface emitting element 422, the right-side irradiation light PLR of the second irradiation pattern is irradiated toward the light distribution region 16, through the shading mask 423 and projection optical system 424. It should be noted that the first irradiation pattern and second irradiation pattern are the same irradiation pattern, as mentioned above.

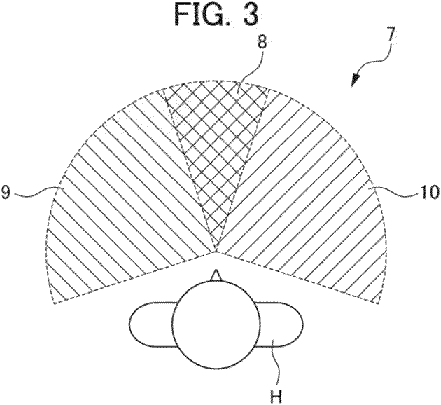

FIG. 3 is a view schematically showing the visual property of a person related to a technical concept of the vehicle headlight device 1 of the present invention described later. In FIG. 3, a forward field of view 7 of a person H is divided into a center field of view 8 which widens at a fixed acute angle to the left and right from a front face, and a left peripheral field of view 9 and right peripheral field of view 10 adjacent on the left and right of the center field of view 8, from the visual property of the person.

The general visual property of a person exhibits a tendency whereby shapes are clearly visible but reaction to movement is delayed, in the center field of view 8. The left peripheral field of view 9 and right peripheral field of view 10 exhibit a tendency whereby shapes are vague, but reaction to movement is fast, i.e. sensitivity to motion is high. The vehicle headlight device 1 of the present invention is based on the idea of actively using the aforementioned such visual property of a person.

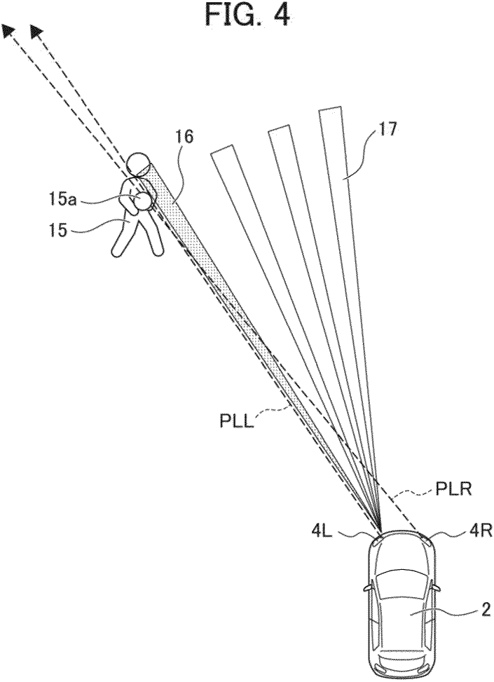

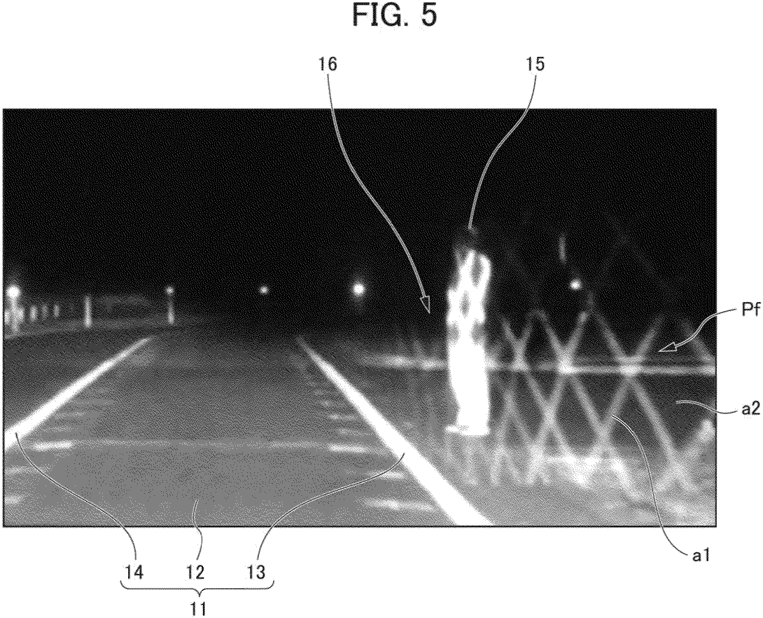

FIG. 4 is a schematic diagram showing, in a plan view, the light distribution region 16 of the left-side pattern irradiation lamp 4L and right-side pattern irradiation lamp 4R of the vehicle headlamp device 1 of an embodiment of the present invention. FIG. 5 is a schematic diagram showing an aspect of a driving field of view at nighttime of the vehicle equipped with the vehicle headlight device as an embodiment of the present invention.

As in FIG. 4, the left-side irradiation light PLL from the left-side pattern irradiation lamp 4L and the right-side irradiation light PLR from the right-side pattern irradiation lamp 4R project the irradiation light to the light distribution region 16 such that the phases of the irradiation patterns overlap and intersect in the target region 15a assumed in front of the vehicle 2. The target region 15a is set in a position reliably irradiating the appeared pedestrian 15 to recognize the existence thereof. It should be noted that the light distribution region 17 of irradiation light from the low beam lamp 5 and high beam lamp 6 is set so as to partially overlap in the light distribution region 16, ahead of the vehicle 2. In FIG. 4, the light distribution region 17 of the irradiation light from the left-side low beam lamp 5 is illustrated representatively.

As in FIG. 5, the divider line 13 and divider line 14 are drawn on both sides of the travel lane 12 of one’s own vehicle 2 on the road 11. A situation is assumed in which the pedestrian 15 stays in the vicinity of the divider line 13. The irradiation light of the irradiation pattern Pf in which the bright region a1 and dark region a2 are alternately repeated is projected in the light distribution region 16 in which this pedestrian 15 is included. The irradiation pattern Pf is prominent within the silhouette of the pedestrian 15.

The inventors, etc. have already proposed technology which quickly captures the presence of a pedestrian 15, by irradiating light from the vehicle headlight device 1 in a stripe-like or grid-like irradiation pattern in which a bright area and dark area are alternately repeated. When irradiating light in the aforementioned such irradiation pattern, acting as if irradiating light which effectively blinks, the presence of the pedestrian 15 is obviously recognized in the peripheral field of view (left-peripheral field of view 9 in FIG. 2) in which sensitivity to motion is high with the visual performance of the driver.

The inventors, etc. further obtained knowledge in the course of repeating experiments that, in the case of the pedestrian 15 moving, there is a problem in that the bright region and dark region do not relatively move within the silhouette of the pedestrian 15, and a phenomenon occurs whereby the driver is hardly aware of the pedestrian 15. In one embodiment of the present invention, this problem is solved by projecting the irradiation light of the irradiation pattern Pf from the left-side pattern irradiation lamp 4L and right-side pattern irradiation lamp 4R, as in FIG. 4.

In other words, from the left-side irradiation light PLL from the left-side pattern irradiation lamp 4L and the right-side irradiation light PLR from the right-side pattern irradiation lamp 4R, irradiation lights of the same irradiation pattern Pf are projected so as to intersect at the target region 15a assumed in front of the vehicle 2. The shape of the irradiation pattern Pf is decided by the shading mask 413 of the left-side pattern irradiation lamp 4L and the shading mask 423 of the right-side pattern irradiation lamp 4R; however, both assume a shape in which the bright region a1 and dark region a2 are alternately repeated.

Although the aforementioned explains a case in which the irradiation patterns Pf from the left-side pattern irradiation lamp 4L and right-side pattern irradiation lamp 4R are the same, the present invention can assume another embodiment differing from this.

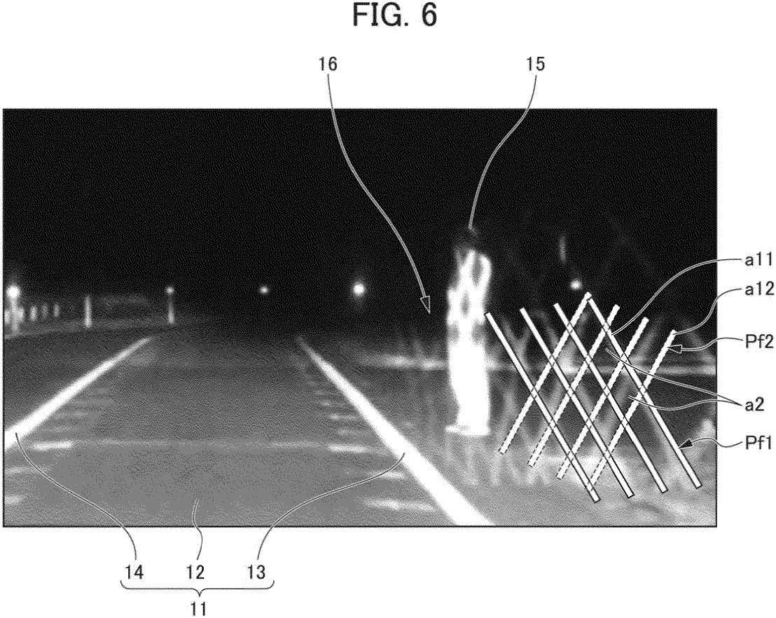

FIG. 6 is a schematic diagram showing an aspect of a driving field of view at night in the vehicle equipped with the vehicle headlight device as another embodiment of the present invention. In the embodiment of FIG. 6, the irradiation pattern of the left-side irradiation light PLL from the left-side pattern irradiation lamp 4L is defined as a stripe-like first irradiation pattern Pf1 such that the first bright regions a11 are arranged in parallel. In addition, the irradiation pattern of the right-side irradiation light PLR from the right-side pattern irradiation lamp 4R is defined as a stripe-like second irradiation pattern Pf2 such that the second bright regions a12 are arranged in parallel. In this case in particular, the second irradiation pattern Pf2 is an irradiation pattern such that intersects with the first bright region a11.

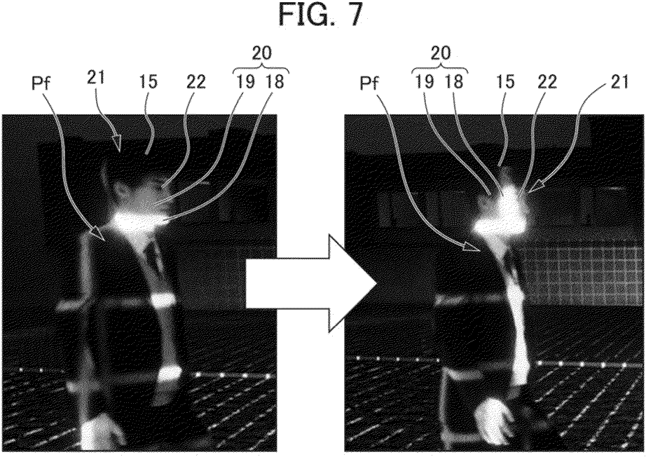

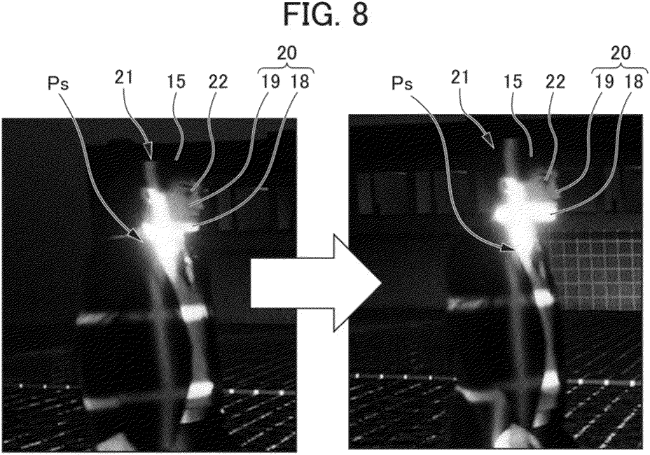

Even if an irradiation pattern in which the bright region and dark region are alternately repeated as mentioned above, in the case of the pedestrian 15 being during movement, a phenomenon occurs in which bright regions and dark regions do not relatively move within the silhouette of the pedestrian 15, and the driver is hardly aware of the pedestrian 15. Regarding this phenomenon, first, a case of an embodiment in which the irradiation patterns Pf from the left-side pattern irradiation lamp 4L and right-side pattern irradiation lamp 4R will be explained by referencing FIGS. 7 and 8.

FIG. 7 is a view showing, in the viewpoint of the driver, an aspect of the pedestrian 15 during movement ahead of the vehicle being irradiated by the irradiation patterns Pf from the left-side pattern irradiation lamp 4L and the right-side pattern irradiation lamp 4R in the vehicle headlight device 1 of the embodiment of the present invention. FIG. 8 shows an example unrelated to the present invention. In other words, it is a view showing, in the viewpoint of the driver, an aspect in which the pedestrian 15 during movement is irradiated by the irradiation pattern Ps from one pattern irradiation lamp, which is either of the left-side pattern irradiation lamp 4L or right-side pattern irradiation lamp 4R.

In the case of the irradiation pattern Pf of FIG. 7, the light/dark pattern 20 from a bright part 18 which is a portion in which the pedestrian 15 during movement is brightly lit by the light of the bright region, and a dark part 19 which is a dark portion not lit corresponding to the dark region, moves within the silhouette 21 of the pedestrian 15. For this reason, the degree of visual stimulus on the side of the driver relative to reflected light from the pedestrian 15 is very remarkable.

In addition, the light/dark pattern 20 moves within the silhouette 21 of the pedestrian 15, and the bright part 18 repeatedly crosses the eye 22 of the pedestrian 15. For this reason, the pedestrian 15 receives stimulus from the flickering of light, and obviously recognizes the presence of the vehicle 2. Therefore, it is possible to improve overlooking of the pedestrian 15 by the driver even under adverse conditions such as nighttime or rain at night, and possible for the pedestrian 15 to be quickly aware of the approach of the vehicle 2.

In contrast, in the case of irradiating the pedestrian 15 during movement with the irradiation light of the irradiation pattern Ps from a single pattern irradiation lamp, unrelated to the present invention in FIG. 8, the light/dark pattern 20 by the bright part 18 and dark part 19 does not move within the silhouette 21 of the pedestrian 15. For this reason, the degree of visual stimulus on the driver side relative to reflected light from the pedestrian 15 is low, and discovery of the pedestrian 15 may be delayed.

In addition, the light/dark pattern 20 does not move within the silhouette 21 of the pedestrian 15, and the dark part 19 may continue to remain at a position of the eye 22 of the pedestrian 15. For this reason, the pedestrian 15 does not receive stimulus from the flickering of light, and is hardly aware of the existence of the vehicle 2.

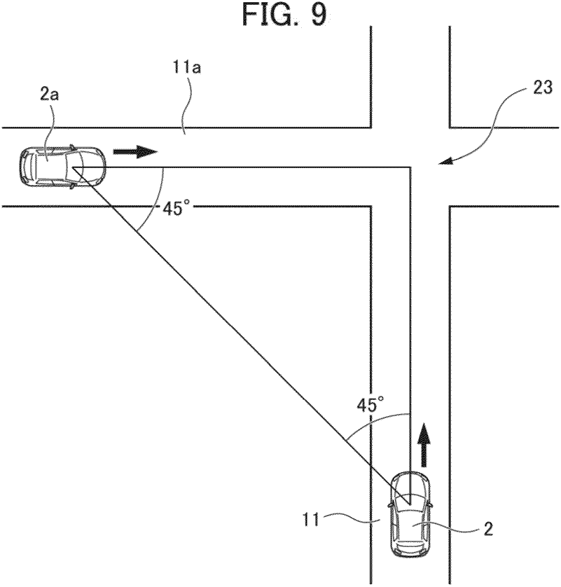

FIG. 9 is a view for explaining the reason for which the phenomenon such as in FIG. 8 occurs. In the case of irradiating the pedestrian 15 during movement with irradiation light of the irradiation pattern Ps from a single pattern irradiation lamp as explained by referencing FIG. 8, the phenomenon in which the light/dark pattern 20 from the bright part 18 and dark part 19 do not move within the silhouette 21 of the pedestrian 15 is considered to be due to a phenomenon similar to the so-called collision course phenomenon. The collision course phenomenon occurs at an intersection 23 having good visibility as in FIG. 9. There is a possibility of the vehicle 2 travelling on a road 11 and a vehicle 2a travelling on a road 11a towards the intersection 23 between the road 11 and road 11a colliding if continuing travel as is.

However, due to always viewing the direction of the same angle as viewing the vehicle 2a from the vehicle 2 (45 degrees in case of FIG. 9), an illusion of being stopped occurs, and this phenomenon is called the collision course phenomenon. In particular, since there is a characteristic of the peripheral field of view of a human hardly recognizing non-moving subjects, if the collision course phenomenon occurs and the other vehicle remaining in the peripheral field of view, there is also a possibility of not being able to recognize each other until entering the intersection 23.

When considering such a collision course phenomenon, a phenomenon similar thereto is considered to occur for the light/dark pattern 20 of the irradiation pattern Ps from the single pattern irradiation lamp on the pedestrian 15 in FIG. 8. In other words, the light/dark pattern 20 of the irradiation pattern Ps relatively displaces within the same irradiation position accompanying movement of the vehicle 2. However, if the pedestrian 15 is moving, the aforementioned such relative displacement of the light/dark pattern 20 within the silhouette 21 of the pedestrian 15 and the displacement of the silhouette 21 itself of the pedestrian 15 are synchronized, and it is considered to seem like the light/dark pattern 20 stopped.

In contrast, when projecting the left-side irradiation light PLL from the left-side pattern irradiation lamp 4L and the right-side irradiation light PLR from the right-side pattern irradiation lamp 4R so that the phases of the irradiation patterns overlap and intersect in the target region 15a assumed ahead of the vehicle 2, the optical axis of the left-side irradiation light PLL and right-side irradiation light PLR differ in angles of tilt in a plan view. Therefore, either one of the left-side irradiation light PLL and right-side irradiation light PLR is an irradiation pattern of a phase deviating from the phase exhibiting the aforementioned such collision course phenomenon. For this reason, synchronization between the aforementioned such relative displacement of the light/dark pattern 20 within the silhouette 21 of the pedestrian 15 and the displacement of the silhouette 21 itself of the pedestrian 15 can be avoided, and the problem such as that explained referencing FIG. 8 is overcome.

In particular, in the case of the light/dark pattern 20 of the irradiation patterns Ps of the left-side irradiation light PLL and right-side irradiation light PLR being the same, since the phase of the same light/dark pattern 20 shift within the silhouette 21 of the pedestrian 15, visual recognition of the irradiation pattern Ps of either one of the left-side irradiation light PLL and right-side irradiation light PLR is not inhibited by the irradiation pattern Ps of the other one of the left-side irradiation light PLL and right-side irradiation light PLR, and is recognized as movement of the same irradiation pattern Ps.

In contrast, in the case of the other embodiment of the present invention as in FIG. 6, the first irradiation pattern Pf1 of the left-side irradiation light PLL from the left-side pattern irradiation lamp 4L, and the second irradiation pattern Pf2 in the irradiation pattern of the right-side irradiation light PLR from the right-side pattern irradiation lamp 4R are different; therefore, one will not inhibit visual recognition of the other. In other words, the first bright region all of the first irradiation pattern Pf1 of the left-side irradiation light PLL and the second bright region a12 of the second irradiation pattern Pf2 of the irradiation pattern of the right-side irradiation light PLR are stripe like intersecting each other, and the left-side irradiation light PLL and right-side irradiation light PLR have optical axes differing in angles of tilt in a plan view. For this reason, either of this first irradiation pattern Pf1 or second irradiation pattern Pf2 is observed so that the phase of the same light/dark pattern 20 shifts within the silhouette 21 of the pedestrian 15 independently from each other.

The configuration of the pattern irradiation lamp 4 in the headlight device for vehicles 1 of the embodiment of the present invention is not limited to the embodiment of FIG. 2. For example, although configured so as to projecting the left-side irradiation light PLL of the irradiation pattern Pf through the shading mask 413 and projection optical system 414 by driving the surface emitting element 412 according to the element drive signal Eds from the light emitter drive circuit 411 of the left-side pattern irradiation lamp 4L, this configuration can assume a different form. In other words, the left-side pattern irradiation lamp 4L may be configured as a projector of a mode which projects the left-side irradiation light PLL of the irradiation pattern Pf by driving a DMD (Digital Mirror Device) containing a micro mirror group according to a signal similar to the element drive signal Eds. The mode of configuring the pattern irradiation lamp 4 as a projector adopting DMD in this way is similarly adapted to the right-side pattern irradiation lamp 4R.

According to the headlight device for vehicles 1 of the present embodiment, the following effects are exerted.

(1) The headlight device for vehicles 1 includes the left-side pattern irradiation lamp 4L as the left-side light irradiator provided on the left side of the vehicle 2 so as to irradiate light in a predetermined light distribution region 16 of the vehicle 2 in a first irradiation pattern in which the bright region and dark region are alternately repeated; and the right-side pattern irradiation lamp 4R as the right-side light irradiation provided on the right side of the vehicle irradiating light in the light distribution region 16 in the second irradiation pattern in which the bright region a1 and dark region a2 are alternately repeated. By at least any of the irradiation light of the first irradiation pattern from the left-side pattern irradiation lamp 4L or the irradiation light of the second irradiation pattern from the right-side pattern irradiation lamp 4R, the light/dark pattern 20 in which the bright part 18 and dark part 19 are alternately repeated moves within the silhouette 21 of the moving pedestrian 15. The presence of the pedestrian 15 during movement is thereby easily recognized from the driver. Overlooking of pedestrians by the driver can be improved even under adverse conditions such as nighttime or rain at night. In addition, it is possible to cause the pedestrian 15 to quickly notice the presence of the vehicle 2 by configuring for the irradiation light to enter the eye 22.

(2) With the vehicle headlight device 1, the first irradiation pattern and second irradiation pattern are the same irradiation pattern Pf. The phase difference at the position of the pedestrian 15 depending on the interval of projection positions between the left-side irradiation light PLL from the left-side pattern irradiation lamp 4L and the right-side irradiation light PLR from the right-side pattern irradiation lamp 4R is clearly recognizable without causing a mistake due to different irradiation patterns. Therefore, an aspect of the light/dark pattern 20 in which the bright part 18 and dark part 19 are alternately repeated is clearly seen within the silhouette 21 of the moving pedestrian 15. The presence of the pedestrian 15 during movement is thereby much more reliably recognized from the driver.

(3) With the vehicle headlight device 1, the first irradiation pattern Pf1 is an irradiation pattern such that the first bright regions all are arranged in parallel, and the second irradiation pattern Pf2 is an irradiation pattern such that the second bright regions a12 intersecting the first bright regions all are arranged in parallel. The phase difference at the position of the pedestrian 15 according to the interval of projection positions between the irradiation light of the first irradiation pattern Pf1 from the left-side pattern irradiation lamp 4L and the irradiation light of the second irradiation pattern Pf2 from the right-side pattern irradiation lamp 4R is clearly recognized without one irradiation pattern causing a mistake due to the other irradiation pattern. Therefore, an aspect of the light/dark pattern 20 in which the bright part 18 and dark part 19 are alternately repeated is clearly seen within the silhouette 21 of the moving pedestrian 15. The presence of the pedestrian 15 during movement is thereby much more reliably recognized from the driver.

### EXPLANATION OF REFERENCE NUMERALS

a1 bright region
a11 first bright region
a12 second bright region
a2 dark region
H person
Pf irradiation pattern
Pf1 first irradiation pattern
Pf2 second irradiation pattern
Ps irradiation pattern
PLL left-side irradiation light
PLR right-side irradiation light
1 headlight device for vehicles
2 vehicle
3 turn signal lamp
4 pattern irradiation lamp
4L left-side pattern irradiation lamp
4R right-side pattern irradiation lamp 5 low beam lamp
6 high beam lamp
7 forward field of view
8 center field of view
9 left-peripheral field of view
10 right-peripheral field of view
11, 11a road
12 travel lane of one’s own vehicle
13 divider line
14 divider line
15 pedestrian
15a target region
16 light distribution region
17 light distribution region
18 bright part
19 dark part
20 light/dark pattern
21 silhouette
22 eye
23 intersection
411 light emitter drive circuit
412 surface emitting element
413 shading mask
414 projection optical system
421 light emitter drive circuit
422 surface emitting element
423 shading mask
424 projection optical system

What is claimed is:

1. A vehicle headlight device comprising:
a left-side photoirradiator provided at a left side of a vehicle so as to irradiate light onto a predetermined light distribution region of the vehicle in a first irradiation pattern in which a bright region and a dark region are alternately repeated; and
a right-side photoirradiator provided at a right side of the vehicle so as to irradiate light onto the light distribution region in a second irradiation pattern in which a bright region and a dark region are alternately repeated.

2. The vehicle headlight device according to claim 1, wherein the first irradiation pattern and the second irradiation pattern are identical irradiation patterns.

3. The vehicle headlight device according to claim 1, wherein the first irradiation pattern is an irradiation pattern such that first bright regions are arranged in parallel, and the second irradiation pattern is an irradiation pattern such that second bright regions which intersect the first bright region are arranged in parallel.
